(19) United States
(12) Patent Application Publication
(10) Pub. No.: US 2010/0259130 A1
(43) Pub. Date: Oct. 14, 2010

(54) Device for energy conversion, in particular a piezoelectric micropower converter

(76) Inventors: Gerald Eckstein, Munchen (DE); Ingo Kühne, Munchen (DE)

Correspondence Address: STAAS & HALSEY LLP, SUITE 700, 1201 NEW YORK AVENUE, N.W., WASHINGTON, DC, 20005, US

(21) Appl. No.: 12/310,620

(22) PCT Filed: Aug. 29, 2007
(86) PCT No.: PCT/EP2007/058952

§ 371 Date: Mar. 2, 2009

(30) Foreign Application Priority Data
Aug. 31, 2006 (DE) 10 2006 040 731.8

(51) Int. Cl. H02N 2/18; H01L 41/053

(52) U.S. Cl. 310/339; 310/344

(57) ABSTRACT

An apparatus, in particular a microsystem, includes a device for energy conversion. The device for energy conversion has a piezoelectric, mechanically vibrating diaphragm structure for converting mechanical energy into electrical energy and/or vice versa, the diaphragm structure being arranged encapsulated in an environment which has a predetermined pressure which is, in particular, lower than an isostatic pressure.

### CROSS REFERENCE TO RELATED APPLICATIONS

This application is based on and hereby claims priority to German Application No. 10 2006 040 731.8 filed on Aug. 31, 2006 and PCT Application No. PCT/EP2007/058952 filed on Aug. 29, 2007, the contents of which are hereby incorporated by reference.

### BACKGROUND OF THE INVENTION

The invention relates to an apparatus, in particular a microsystem, which comprises a device for energy conversion.

There is increasing demand for microsystems in the fields of sensor technology, actuator technology, in data communications and in the field of automotive engineering and automation technology. Microsystems of this type have to be supplied with energy to operate. At the same time, the microsystems are intended to be as independent, i.e. autarkic, as possible.

Conventional autarkic systems are known which are operated solely by solar energy conversion. A disadvantage here is that all areas of application in which solar energy cannot be made usable are ruled out. Furthermore, where solar energy is used via solar cells, difficulties arise with their miniaturization and integration into CMOS technology.

### SUMMARY

One potential object is to provide an energy conversion for an appliance, in particular for a microsystem, in a simple, efficient and cost-effective manner. The appliance should be capable of being integrated into known semiconductor technologies and essentially maintenance-free. Further requirements are cable-free operation and optimum miniaturization of the appliance. The appliance should be capable of being used as a sensor, as an actuator and/or for data transmission and/or as an energy source or generator and/or as a signaling transmitter.

The solution for the energy conversion lies in converting from mechanical energy, in particular vibrations which are present in the environment of the appliance, in particular of the microsystem, mechanical energy into electrical energy. This means vibration energy is converted into electrical energy. A utilization of energy occurs by using the deflection of a piezoelectric membrane structure which absorbs the vibrations. Here, energy efficiency can be optimized if the membrane structure is arranged encapsulated in an environment which has a predetermined pressure which is, in particular, lower than an isostatic pressure.

The apparatus forms a generator which thus essentially constitutes a spring-mass system which is capable of converting mechanical energy into electrical energy. The electrical energy is consequently available for an autarkic microsystem or it can be stored intermediately. The mechanical energy to be converted is obtained by the generator, in that it is coupled to the surrounding vibrations or fluctuations which one would like to utilize.

The piezoelectric generator fundamentally includes the membrane structure which contains a functional piezoelectric layer. An alternating deflection of the membrane structure leads to mechanical tension in the piezoelectric layer such that a continuous charge transfer occurs within this layer. This charge transfer can be used for exploiting energy.

According to an advantageous embodiment, the membrane structure is arranged encapsulated in an environment which has a vacuum. By this, frictional forces in the deflection of the membrane structure during its actuation can be minimized so that a maximum energy yield can be achieved.

According to a further advantageous embodiment, to form the membrane structure a piezoelectric layer arranged between two electrode layers is arranged on a wafer in such a way that at least the electrode layer lying adjacent to the wafer extends beyond a wafer notch.

According to a further advantageous embodiment, to form the membrane structure the piezoelectric layer arranged between two electrode layers is arranged on a carrier layer on the wafer in such a way that at least the carrier layer lying adjacent to the wafer extends beyond the wafer notch.

According to a further development, the membrane structure is arranged between an upper and a lower cover wafer in such a way that the membrane structure can vibrate in a formed cavity. The intended pressure for operating the device for energy conversion is provided in the cavity. The use of an upper and a lower cover wafer for encapsulating the device for energy conversion offers on the one hand the advantage that the mechanical damping of the system due to surrounding air can be reduced considerably. This leads to the higher energy yield. On the other hand, a protection is provided against external environmental influences such as e.g. dirt and moisture. Ultimately, due to the possibility of wafer-level packaging, an appliance can be achieved with small dimensions as all the production steps can be carried out using known methods from semiconductor technology.

According to a further embodiment, the membrane structure is arranged between the lower and the upper cover wafer in such a way that electrical terminals of the electrode layers lead out of the cavity. Connection of the apparatus to an energy consumer or an intermediate store is thereby possible.

Advantageously, the upper and the lower cover wafer are brought into contact with the wafer such that the wafer notch is enclosed so as to form the cavity. It can furthermore be provided that at least the upper cover wafer has a recess facing the wafer notch.

According to a further embodiment, the upper and/or the lower cover wafer are composed of glass. In an embodiment of this type, the connection of the upper and of the lower cover wafer to the wafer can be produced by anodic bonding.

In an alternative embodiment, the upper and/or the lower cover wafer are composed of silicon. In this case, the connection of the upper and of the lower cover wafer to the wafer can be produced by silicon fusion bonding, this connection method also being known.

According to a further advantageous embodiment, the electrode layers and the piezoelectric layer are arranged in the area of the wafer notch. In this way, the piezoelectric layer can capture the vibration oscillations effectively.

According to a further advantageous embodiment, the membrane structure is mechanically coupled to an additional mass. In this way, the membrane structure can be made particularly sensitive to mechanical energy in the form of vibrations.

The additional mass can advantageously lie on the membrane structure and/or be integrated in the carrier layer in the area of the wafer notch. In the first case, lead, for example, can be applied to an electrode layer, for example by melting it on. In the second case, the carrier layer can have a boss structure. A “boss structure” is a membrane stiffened in the center.

In order to achieve a maximum deflection of the membrane structure and thus a maximized energy yield, it is advantageous for the connection of the additional mass to the membrane structure to be effected such that the stiffness is impaired only in a small surface area and as large as possible a surface is available for the transport of charge.

According to a further advantageous embodiment, the at least one membrane structure is provided as a spring-mass system with a resonance frequency such that this resonance frequency falls within a frequency band of a vibration.

Operation of the membrane structure with resonance frequency enables a maximized energy yield.

According to a further advantageous embodiment, the resonance frequency of the membrane structure is adjustable, in particular by varying the mass and/or the spring stiffness. In addition, the membrane structure can have discrete mass areas which are fixed such that only the unfixed mass vibrates. Also, a membrane structure can have areas with different spring stiffnesses which can be selected and activated to provide different resonance frequencies.

According to a further advantageous embodiment, at least one of the electrode layers has a digital progression. Digital here means merely “subdivided”, i.e. “not continuous”. The digital electrode surfaces are preferably laid out such that they satisfy the respective equipotential surfaces with regard to the mechanical tension in the layer, so as to reduce the negatively acting electro-mechanical feedback of the piezoelectric membrane.

According to a further advantageous embodiment, the device for energy conversion is fashioned as a sensor, as an actuator, for data communication and in the field of automotive engineering and automation technology and/or as an energy source and/or as a signal transmitter.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a first exemplary embodiment of a piezoelectric membrane structure; and

FIG. 2 shows a second exemplary embodiment of a piezoelectric membrane structure.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

According to the exemplary embodiments, a device for energy conversion is used as an energy source in the form of a piezoelectric micropower generator.

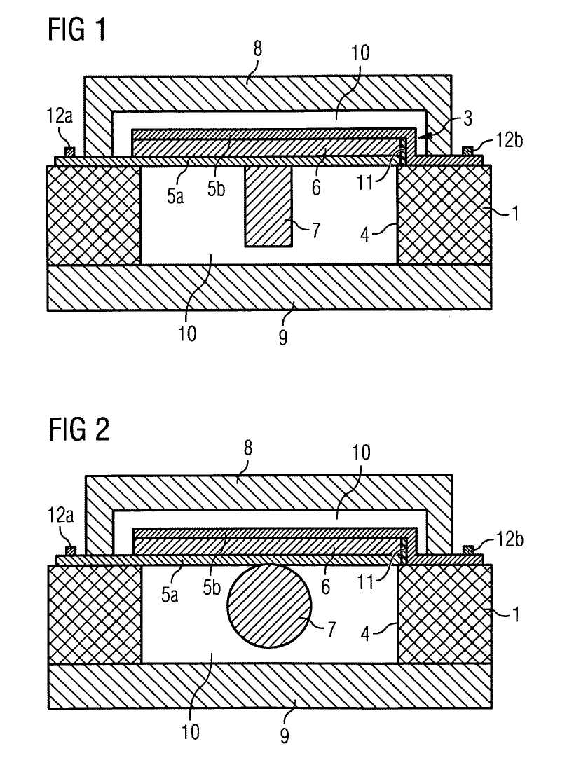

FIG. 1 shows a wafer 1 with a wafer notch 4 introduced therein. The wafer 1 can for example be composed of silicon and/or SOI (silicon on insulator). In the area of the wafer notch 4, a membrane structure 3 is arranged on the wafer 1. The membrane structure 3 is connected to the wafer 1 such that it can vibrate. The membrane structure 3 comprises two electrode layers 5a, 5b between which a piezoelectric layer 6 is arranged. The electrode layers 5a, 5b can for example be composed of platinum, titanium and/or platinum/titanium or else from gold. The piezoelectric layer 6 is composed for example of PZT, AlN and/or PTFE or can also be composed of the material ZnO. The piezoelectric layer 6 can moreover be produced as a layer sequence or individually as a PVD thin layer (less than 5 μm), as a sol/gel layer (less than 20 μm) and/or as a glued bulk piezolayer.

The membrane structure can, as opposed to the illustration in the drawing, also be mounted on a carrier layer which is produced for example from silicon, polysilicon, silicon dioxide and/or Si₃N₄. In this embodiment, it is advantageous if the carrier layer is connected to the wafer 1 such that it can vibrate and at the same time extends beyond the wafer notch 4. The connection between carrier layer and wafer 1 can be produced for example by gluing or fusing. In the exemplary embodiment, the carrier layer is produced by the lower electrode layer 5a, i.e. the electrode layer adjacent to the wafer 1. The lower electrode layer consequently simultaneously assumes the function of carrier layer.

The membrane structure 3 is arranged in a cavity 10 which is formed by an upper cover wafer 8 and a lower cover wafer 9 and the wafer notch 4 which are respectively connected directly to the wafer 1 or indirectly to the wafer 1. The lower cover wafer 9 has in cross-section a planar form, while the upper cover wafer 8 encompasses a recess into which the membrane structure 3 partially extends. For the electrical contacting of the membrane structure 3, the electrode layers 5a, 5b respectively lead out of the cavity 10 and are connected to a respective contact pad 12a, 12b made e.g. of platinum. The electrode layers 5a, 5b run in the exemplary embodiment on the surface of the wafer 1. This is not mandatory. The electrode layer 5a, 5b could also be guided out through electrical layers running in the wafer 1 and be contactable there. The reference character 11 designates here an insulation on a lateral edge of the piezoelectric layer 6 and the electrode layer 5a, so as to prevent a short circuit between the electrode layer 5a and the electrode layer 5b, which in the area of the insulation runs along the lateral edges from the top of the piezoelectric layer 6 to the wafer 1 and from there outside the cavity 10.

In order to use a deflection of the membrane structure due to vibrations to obtain energy, a mass 7 is arranged on the membrane structure 3 which mass extends from the electrode layer 5a in the direction of the wafer notch 4. The additional mass 7 is coupled to the membrane structure 3 such that vibrations can be captured more effectively by the membrane structure 3 and the piezoelectric layer 6.

According to the exemplary embodiment shown in FIG. 1, a mass, which is composed of wafer material and can be accelerated on the basis of vibrations, is coupled to the membrane structure 3. The production of the additional mass 7 can be effected through application of the electrode layer 5a to a top of the wafer 1 and through one or more subsequent etching processes from the back of the wafer 1.

Alternatively, as is shown e.g. in the second exemplary embodiment according to FIG. 2, an additional mass 7 in the shape of a sphere can be coupled to the membrane structure. The sphere can, for example, be formed of lead or another material and be melted on to the electrode layer 5a. It is advantage in this variant for the contact area of the additional mass 7 on the membrane structure 3 to be very small so that only limited stiffening of the membrane occurs.

By selection of the additional mass 7, the resonance frequency of the membrane structure can be adjusted in a simple and effective manner. On the other hand, the resonance frequency can also be adjusted by stipulating the stiffness of the membrane structure. A further facility for adjusting the resonance frequency is the selection of appropriate materials for the membrane structure 3 to determine spring stiffness of the membrane structure 3. The size of the wafer notch 4 can also be selected and adapted to the desired resonance frequency. With regard to the additional mass 7, there are no limits on the selection of material. Particularly dense materials enable particularly compact embodiments of a piezoelectric micropower generator for vibrations.

The upper and the lower cover wafer 8, 9 can be composed of glass or from silicon. If the upper and/or the lower cover wafer is/are composed of glass, then a method called anodic bonding is carried out to connect it/them to the wafer 1.

In this known connection method, the connection partners (lower cover wafer 9 and wafer 1 or wafer 1 and upper cover wafer 8) are preferably placed on top of one another in a vacuum and heated. In the process, a potential is applied to the upper and the lower cover wafer 8, 9 and the arrangement is placed under slight pressure. The heating causes the ions in the glass to be able to move more freely. Due to the voltage applied to the upper and the lower cover wafer, charge displacements are produced such that a space charge region emerges. The respective connection partners thus attract one another. The surfaces of the respective connection partners are pulled increasingly tightly against one another due to the electric fields. Ultimately, a point is reached at which the gap is so small that the surface atoms of the glass can react chemically with those of the wafer, e.g. a silicon wafer. Chemical compounds form between the silicon of the wafer and the oxygen from the silicon oxide of the glass. As a result, a firm connection between the connection partners is created, a vacuum being produced simultaneously in the cavity 10 in which the membrane structure is situated.

If the upper and/or the lower cover wafer are composed of silicon, then a production of the connection between the upper and/or the lower cover wafer and the wafer is effected by silicon fusion bonding. To this end, the contact surfaces of the upper and/or the lower cover wafer 8, 9 and of the wafer 1 are firstly cleaned. A thin film of water is located on the contact surfaces. When the respective connection partners are placed in contact, hydrogen bonding is produced. By heating up this bond to temperatures between 200° C. and 300° C., preferably 200° C., a firm silicon crystal structure is produced in the region of the contact surfaces. This method is particularly suitable where no vacuum, but a different pressure is to be generated in the cavity, but which, to maximize the energy efficiency of the generator is lower than an ambient pressure.

According to the exemplary embodiment described, the device for energy conversion is used as a piezoelectric micropower generator which, utilizing pressure fluctuations which are present in the environment of the microsystem, enables the supply of energy to apparatuses and microsystems which are in this way autarkic. The piezoelectric effect is utilized here not only in a spatial dimension such as e.g. in the arrangement of a bar, but in the entire surface of the membrane structure 3 so that an effective energy yield can be achieved.

Digital electrode surfaces, i.e. subdivided, electrodes which are not continuous make it possible to reduce the negatively acting electromechanical feedback of the piezoelectric membrane during energy conversion.

The piezoelectric generator is preferably implemented in MEMS technology (MEMS=micro electro mechanical system). Besides integratability into CMOS technology (CMOS=complementary metal oxide semiconductor) this also offers the advantage of, in particular vacuum-tight, encapsulation at wafer level, wafer-level packaging by the wafer bonding method. The structure of the piezoelectric generator corresponds here to a three-layer sandwich structure, in which the three wafers adjusted relative to one another (the wafer 1 and the cover wafers 8, 9) are bonded. In the process, the upper and the lower cover wafer from the encapsulation of the actual generator, the membrane structure 3.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-19. (canceled)

20. A microsystem apparatus, comprising:
an energy conversion device including a piezoelectric membrane structure configured to vibrate mechanically, the energy conversion device converting mechanical energy into electrical energy, the piezoelectric membrane structure being encapsulated in an environment having a predetermined pressure lower than an isostatic pressure.

21. The microsystem apparatus as claimed in claim 20, wherein the piezoelectric membrane structure is encapsulated in a vacuum.

22. The microsystem apparatus as claimed in claim 20, further comprising a main wafer and a wafer notch introduced in the wafer,
wherein the piezoelectric membrane structure includes a piezoelectric layer arranged between two electrode layers on the main wafer such that at least the electrode layer lying adjacent to the main wafer extends beyond the wafer notch.

23. The microsystem apparatus as claimed in claim 20, further comprising a main wafer and a wafer notch introduced in the wafer,
wherein the piezoelectric membrane structure includes a piezoelectric layer arranged between two electrode layers, one of which is a carrier layer arranged on the main wafer such that at least the carrier layer lying adjacent to the main wafer extends beyond the wafer notch.

24. The microsystem apparatus as claimed in claim 22, further comprising an upper cover wafer and a lower cover wafer, the piezoelectric membrane structure being arranged between the upper and lower cover wafers such that the piezoelectric membrane structure can vibrate in a cavity formed between the upper and lower cover wafers.

25. The microsystem apparatus as claimed in claim 24, wherein the piezoelectric membrane structure is arranged between the upper cover wafer and the lower cover wafer such that electrical terminals of the electrode layers extend out of the cavity.

26. The microsystem apparatus as claimed in claim 24, wherein the upper cover wafer and the lower cover wafer are brought into contact with the main wafer such that the wafer notch is enclosed to form the cavity.

27. The microsystem apparatus as claimed in claim 26, wherein at least the upper cover wafer has a recess defined therein facing the wafer notch.

28. The microsystem apparatus as claimed claim 24, wherein the upper cover wafer and/or the lower cover wafer are composed of glass.

29. The microsystem apparatus as claimed in claim 28, wherein the upper cover wafer and the lower cover wafer are connected to the main wafer by anodic bonding.

30. The microsystem apparatus as claimed in claim 24, wherein the upper cover wafer and/or the lower cover wafer are composed of silicon.

31. The microsystem apparatus as claimed in claim 30, wherein the upper cover wafer and the lower cover wafer are connected to the main wafer is produced by silicon fusion bonding.

32. The microsystem apparatus as claimed in 24, wherein the electrode layers and the piezoelectric layer are arranged at the water notch.

33. The microsystem apparatus as claimed in claim 22, further comprising a mass mechanically coupled to the piezoelectric membrane structure.

34. The microsystem apparatus as claimed in claim 33, wherein the mass is adjacent to the piezoelectric membrane structure and/or is integrated in one of the electrode layers at the wafer notch.

35. The microsystem apparatus as claimed in claim 20, wherein the piezoelectric membrane structure is provided as a spring-mass system with a resonance frequency being within a frequency band of a vibration.

36. The microsystem apparatus as claimed in claim 35, wherein the resonance frequency of the piezoelectric membrane structure is adjustable by varying a mass and/or a spring rigidity.

37. The microsystem apparatus as claimed in claim 22, wherein at least one of the electrode layers is generated digitally.

38. The microsystem apparatus as claimed in claim 20, wherein the energy conversion device is a sensor.

39. The microsystem apparatus as claimed in claim 20, wherein the energy conversion device is an actuator for data communication.

40. The microsystem apparatus as claimed in claim 20, wherein the energy conversion device is an energy source.

41. The microsystem apparatus as claimed in claim 20, wherein the energy conversion device is a signaling transmitter.

42. A microsystem apparatus, comprising:
a main wafer having a wafer notch defined therein;
an upper cover wafer disposed above the main wafer;
a lower cover wafer disposed below the main wafer; and
a membrane structure arranged on the main wafer within a cavity defined between the upper cover wafer, the lower cover wafer and the wafer notch and having a pressure lower than an isostatic pressure, the membrane structure including at least two electrode layers and a piezoelectric layer disposed therebetween, the membrane structure vibrating in the cavity such that mechanical energy present in an environment of the microsystem apparatus is converted into electrical energy.

43. The microsystem apparatus as claimed in claim 42, wherein one of the at least two electrode layers lies adjacent to the main wafer and extends beyond the wafer notch.
